(19) United States
(12) Patent Application Publication
(10) Pub. No.: US 2026/0093188 A1
(43) Pub. Date: Apr. 2, 2026

(54) ASSEMBLY IN A MICROLITHOGRAPHIC PROJECTION EXPOSURE APPARATUS

(71) Applicant: Carl Zeiss SMT GmbH, Oberkochen (DE)

(72) Inventor: Ulrich SCHOENHOFF, Ulm (DE)

(21) Appl. No.: 19/413,157

(22) Filed: Dec. 9, 2025

Related U.S. Application Data
(63) Continuation of application No. PCT/EP2024/064477, filed on May 27, 2024.

(30) Foreign Application Priority Data
Jun. 27, 2023 (DE) 10 2023 206 041.8

(51) Int. Cl. G03F 7/00; G02B 7/182

(52) U.S. Cl. CPC G03F 7/70825; G02B 7/182; G03F 7/70525

(57) ABSTRACT

An assembly, such as in a microlithographic projection exposure apparatus having: an optical element; and at least one weight compensating device with a passive magnetic circuit for generating a magnetic field, which causes a force for at least partial compensation of the weight acting on the optical element, and an active component for generating an actively controllable force transmitted to the optical element. The at least one weight compensating device is coupled to the optical element via a pin mounted in an articulated manner, and at least three Lorentz actuators each designed for exerting a controllable force on the optical element, wherein at least one of these Lorentz actuators is fixed directly to the optical element.

### CROSS-REFERENCE TO RELATED APPLICATIONS

The present application is a continuation of, and claims benefit under 35 USC 120 to, international application No. PCT/EP2024/064477, filed May 27, 2024, which claims benefit under 35 USC 119 of German Application No. 10 2023 206 041.8, filed Jun. 27, 2023. The entire disclosure of each of these applications is incorporated by reference herein.

### FIELD

The disclosure relates to an assembly in a microlithographic projection exposure apparatus.

### BACKGROUND

Microlithography is used for producing microstructured components, such as integrated circuits or LCDs. The microlithography process is performed in what is known as a projection exposure apparatus, which comprises an illumination device and a projection lens. The image of a mask (=reticle) illuminated via the illumination device is in this case projected via the projection lens onto a substrate (for example a silicon wafer) coated with a light-sensitive layer (photoresist) and arranged in the image plane of the projection lens, in order to transfer the mask structure to the light-sensitive coating on the substrate.

In a projection exposure apparatus designed for EUV (for example for wavelengths of for instance approximately 13 nm or approximately 7 nm), mirrors are used as optical components for the imaging process because of, in general, an unavailability of light-transmissive materials. These mirrors may for example be mounted on a supporting frame and be designed as at least partially manipulable, in order to allow a movement of the respective mirror in six degrees of freedom (i.e. with respect to displacements in the three spatial directions x, y and z and also with respect to rotations Rx, Ry and Rz about the corresponding axes). This can help allow compensations to be made for changes in the optical properties that occur for instance during the operation of the projection exposure apparatus, for example as a result of thermal influences.

It is for example known to use in a projection lens of an EUV projection exposure apparatus for the manipulation of optical elements such as mirrors in up to six degrees of freedom—as schematically indicated in FIG. 13—three actuator arrangements, which respectively comprise at least two Lorentz actuators 1302 and 1303, 1304 and 1305 and also 1306 and 1307 (i.e. two actively activatable axes of movement in each case). Also provided in the construction from FIG. 13 for each of these actuator arrangements or for each associated point of force introduction there is in each case a weight compensating device (also referred to as “MGC”=“Magnetic Gravity Compensator”) bearing the weight of an optical element or mirror 1300, in order to reduce the energy consumption of the active or controllable adjusting elements, so that in this respect no permanent energy flow with accompanying heat generation is used. The weight compensating device can be adjustable to a certain holding force, which is transmitted to the mirror 1300 via a mechanical element (pin) 1315, 1325 or 1335 mechanically coupled to the mirror 1300. Furthermore, it is also known, for example, to additionally design the weight compensating device for exerting a controllable force.

Different approaches are known with regard to connecting the Lorentz actuators and the weight compensating device. One problem that occurs during operation is for example that, depending on the specific configuration, comparatively high parasitic moments or forces can be transmitted to the mirror, such as via the Lorentz actuators, this in turn can lead to undesired deformations of the optically effective surface of the respective mirror and thus to impairment of the performance of the optical system.

Within the scope of increasing demands on the projection exposure apparatus with regard to achieved resolution and contrast and the associated increasing numerical apertures and mirror sizes, the coupling both of the Lorentz actuators and the weight compensating device thus can represent an increasingly demanding challenge.

Reference is made merely by way of example to DE 10 2009 054 549 A1, WO 2012/084675 A1, DE 10 2018 202 694 A1 and DE 10 2018 207 949 A1.

### SUMMARY

The present disclosure seeks to provide an assembly in a microlithographic projection exposure apparatus that allows actuation of an optical element that is as disruption- and deformation-free as is reasonably possible, while at least largely avoiding certain issues.

In an aspect, the disclosure provides an assembly, for example, in a microlithographic projection exposure apparatus. The assembly has:
an optical element;
at least one weight compensating device with
   a passive magnetic circuit for generating a magnetic field, which causes a force for at least partial compensation of the weight acting on the optical element, and
   an active component for generating an actively controllable force transmitted to the optical element;
   wherein the at least one weight compensating device is coupled to the optical element via a pin mounted in an articulated manner; and
at least three Lorentz actuators each designed for exerting a controllable force on the optical element, wherein at least one of these Lorentz actuators is fixed directly to the optical element.

According to an embodiment, the active component of the weight compensating device comprises at least one coil to which electric current can be applied. This coil can be located in the stray field of the passive magnetic circuit. In some embodiments, the active component can also have mechanically connected additional Lorentz actuators, a unit (for example designed with piezo actuators) for adjusting magnet positions in the passive magnetic circuit or a device for manipulating the magnetic field strength in the passive magnetic circuit by actively changing the temperature.

The disclosure provides, for example, the concept of, in an assembly for actuating an optical element (such as a mirror for example in a microlithographic projection exposure apparatus), configuring a weight compensating device provided for at least partial compensation of the weight acting on the optical element with an active component provided in addition to an existing passive magnetic circuit for the purpose of generating an actively controllable force transmitted to the optical element. In combination with this “active” configuration of the weight compensating device, the disclosure further provides, for example, the idea of, in the case of one or more of the Lorentz actuator(s) designed for exerting a controllable force on the optical element, dispensing with any articulated connection (for example in the form of a pin mounted in an articulated manner) in favor of direct fixing to the optical element with regard to the actuator component (for example the magnet in a magnet-coil pair forming the respective Lorentz actuator) mechanically connected to the optical element and movable with the optical element.

With the combination described above, the disclosure can make use of the fact that, as a result of the abovementioned “active” configuration of the weight compensating device (i.e. with an active component comprising, for example, a coil to which electric current can be applied), precise force transmission to the optical element along the (vertical) direction of force transmission of this active component can already be achieved via the weight compensating device. As a result, the Lorentz actuators can now be relieved of transmitting static forces to the optical element, so that parasitic forces and moments transmitted to the optical element via the Lorentz actuators are significantly reduced in this respect. At the same time, on the part of the Lorentz actuators—as a result of at least partially dispensing with a pin mounted in an articulated manner for connecting them—the transmission of parasitic forces and moments, which would occur in the event of a connection via flexures, can also be partially or completely avoided. With regard to the connection of the Lorentz actuators to the optical element to be actuated, firstly certain undesirable features associated with connection via flexures can be avoided and secondly certain undesirable features associated with direct fixing according to the disclosure in principle can be minimized (using the “active” configuration of the weight compensating device) as a result.

In this case, according to the disclosure, potential increased expenditure for the increased number of actuators used in total (including for the active component of the weight compensating device) as well as associated feed or amplifier components and desired actuation or control electronics can be deliberately accepted in order to in return achieve desirable features described above, such as the reduction of parasitic forces and moments transmitted to the optical element.

According to an embodiment, at least three, such as six, of the Lorentz actuators are fixed directly to the optical element. In other words, for at least three, such as six, of the Lorentz actuators, the actuator component (typically the magnet of the magnet-coil pair forming the Lorentz actuator) respectively mechanically connected to the optical element and movable together with it is fixed directly to the optical element.

According to the disclosure, the weight compensating device can be coupled to the optical element via a pin mounted in an articulated manner. In this case, a natural frequency of this coupling can be less than 3 times, such as less than 2 times, for example less than 1.5 times, the control bandwidth.

According to an embodiment, the assembly has at least two, such as at least three, weight compensating devices.

According to an embodiment, the assembly has three actuator units, wherein each of these actuator units has a weight compensating device and two Lorentz actuators, wherein these Lorentz actuators and the weight compensating device each run to a common point of force introduction.

According to an embodiment, the assembly has three actuator units, wherein each of these actuator units has a weight compensating device, a Lorentz actuator and an inertial actuator, wherein the Lorentz actuator, the inertial actuator and the weight compensating device each run to a common point of force introduction.

According to an embodiment, the assembly has more than three, for example more than six, Lorentz actuators for exerting a controllable force on the optical element in the vertical direction.

According to one embodiment, the assembly has, for exerting a controllable force on the optical element, at least three inertial actuators, for example at least six inertial actuators, for partially decoupling a reaction path accompanying the exertion of the controllable force on the optical element. In this context, reference is made to DE 10 2016 202 408 A1 and DE 10 2013 201 081 A1 by way of example.

According to an embodiment, the assembly further has a controller, wherein this controller is designed to separately actuate the weight compensating device for exerting static forces and the Lorentz actuators for exerting dynamic forces.

According to an embodiment, the actuation of the weight compensating device is performed via an integrator branch (I component), and the actuation of the Lorentz actuators is performed via a separate PD branch.

According to an embodiment, the optical element is a mirror.

The disclosure further relates to an optical system, for example of a microlithographic projection exposure apparatus, which has at least one assembly having the features described above.

Even though the disclosure has been described above—merely by way of example—on the basis of use in optical components for EUV projection exposure apparatuses, use in optical components for other optical systems is of course also conceivable, such as also for higher operating wavelengths, for example in DUV projection exposure apparatuses (DUV=deep ultraviolet) with typical wavelength ranges of between 240 nm and 255 nm, or for optical systems with operation in a VUV range (vacuum ultraviolet range) between EUV and DUV.

Further configurations of the disclosure can be gathered from the description and the dependent claims.

The disclosure will be explained in detail below on the basis of exemplary embodiments illustrated in the appended figures.

### BRIEF DESCRIPTION OF THE DRAWINGS

In the drawings:

FIGS. 1, 2A-2B, 3A-3B, 4A-4C show schematic representations for explaining possible embodiments of an assembly according to the disclosure;

FIGS. 5-11 show schematic representations for explaining possible configurations of a control loop for actuating an assembly according to the disclosure in different embodiments;

FIG. 12 shows a schematic representation of a projection exposure apparatus designed for operation in the EUV range; and

FIG. 13 shows a schematic representation for explaining a conventional construction for the manipulation of a mirror in six degrees of freedom.

### DETAILED DESCRIPTION

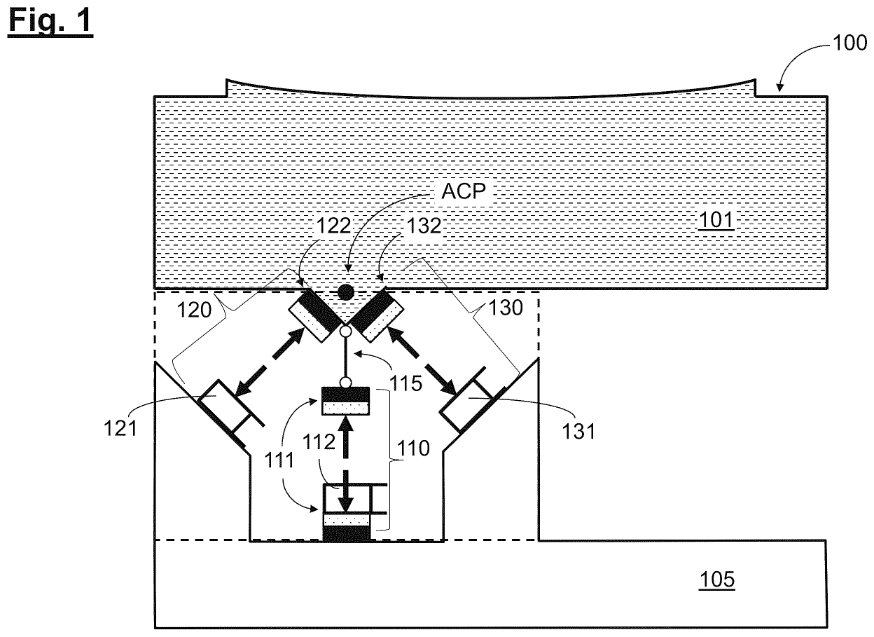

Different embodiments of an assembly according to the disclosure are described below with reference to the schematic representations in FIGS. 1-3.

These embodiments share the common factors that firstly a weight compensating device present in the respective assembly for at least partial compensation of the weight acting on an optical element such as a mirror (in addition to the existing passive magnetic circuit) is “active”, i.e. is configured with an active component for generating an actively controllable force transmitted to the optical element, and that secondly, in the case of one or more of the Lorentz actuator(s) further designed for exerting a controllable force on the optical element, any articulated connection to the optical element (for example in the form of a pin mounted in an articulated manner) is dispensed with in favor of direct fixing to the optical element.

FIG. 1 shows a schematic representation of an assembly 100 having an optical element 101 in the form of a mirror, a supporting frame 105 and one of for example a total of three actuator units, wherein this actuator unit comprises a weight compensating device 110 and two Lorentz actuators 120, 130 (each comprising a coil 121 or 131 and a magnet 122 or 132). “ACP” denotes a common point of force introduction of the Lorentz actuators 120, 130 and the weight compensating device 110. The mechanical connection of the weight compensating device 110 (with a passive magnetic circuit 111 also indicated in FIG. 1) to the optical element 101 is performed via a pin 115 mounted via flexures. Furthermore, the weight compensating device 110 comprises, in addition to the passive magnetic circuit 111, an active component for generating an actively controllable force on the optical element 101, wherein this active component in the exemplary embodiment (but without the disclosure being restricted to this) has a coil 112 to which electric current can be applied and which is located in the stray field of the passive magnetic circuit 111. In further embodiments, the active component may also have mechanically connected additional Lorentz actuators, a unit (for example designed with piezo actuators) for adjusting magnet positions in the passive magnetic circuit or a device for manipulating the magnetic field strength in the passive magnetic circuit by actively changing the temperature.

Unlike in the case of mechanical connection of the weight compensating device 110, coupling via the Lorentz actuators 120, 130 is performed in such a way that, in the Lorentz actuators 120, 130, the magnet 122 or 132 respectively coupled via magnetic forces to the coil 121 or 131 fixed on the supporting frame side is fixed directly to the optical element 101. The coil and the magnet can also be reversed. With regard to the Lorentz actuators 120, 130, a mechanically guided articulated connection of the respective magnets of the Lorentz actuators via a pin mounted in an articulated manner is thus dispensed with in favor of direct fixing to the optical element 101. As a result, transmission of parasitic moments via flexures is also avoided in this respect.

At the same time, due to the fact that static forces can be “transferred” to the optical element 101 by the weight compensating device 110 as a result of the “active” design of the weight compensating device 110 and the Lorentz actuators 120, 130 are accordingly relieved of transmitting static forces to the optical element 101, transmission of parasitic forces and moments associated with direct fixing of the Lorentz actuators 120, 130 to the optical element 101 in principle is also significantly reduced.

Furthermore, the “active” design of the weight compensating device 110 is used for exerting static forces on the optical element 101, with the result that the mechanical connection of the weight compensating device 110 to the optical element 101 via the pin 115 mounted in an articulated manner can be designed to be comparatively pliant. In this case, the (actuator) natural frequency of this coupling can for example be less than 3 times, such as less than 2 times, for example less than 1.5 times, the control bandwidth. Here, the actuator natural frequency is understood to mean the natural frequency of the eigenmodes in the direction of action of the actuator, wherein these eigenmodes are formed from the axial flexibility of the pin and its joints and the connected magnet mass (or coil mass with reversed installation) of the actuator.

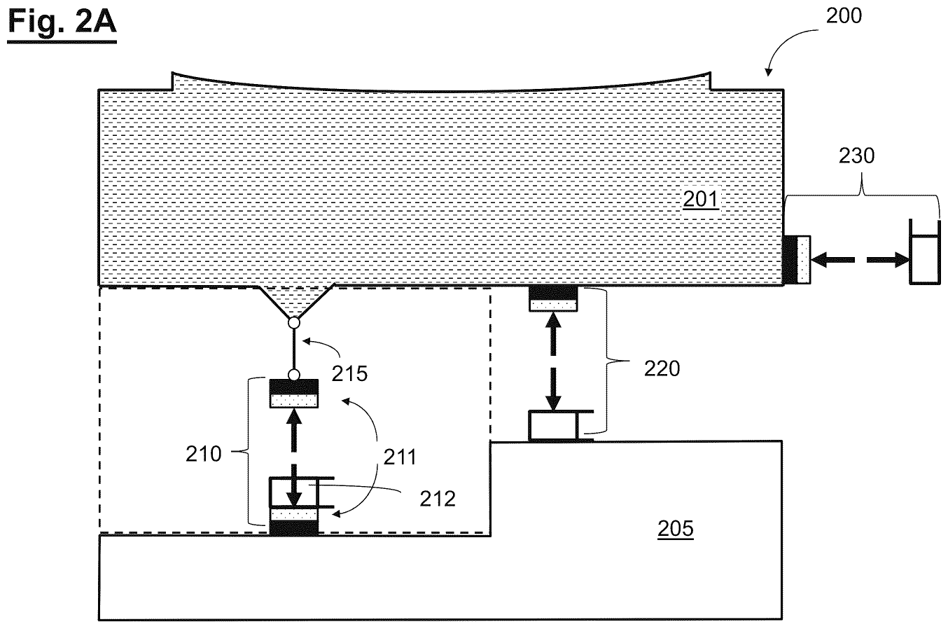

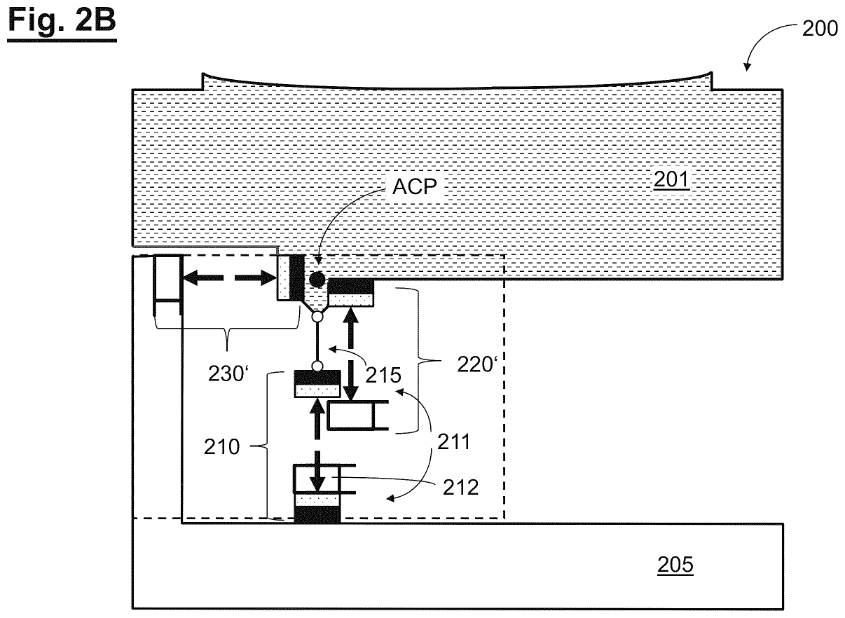

FIG. 2A shows a schematic representation of a further embodiment of an assembly 200 according to the disclosure, wherein analogous or substantially functionally identical components in comparison to FIG. 1 are denoted by reference numerals increased by “100”.

The embodiment according to FIG. 2A differs from that of FIG. 1 in that the Lorentz actuators 220, 230 are arranged in other positions with respect to the optical element 201 to be actuated. For example, the Lorentz actuators 220, 230 can be arranged outside the actuator unit comprising the weight compensating device 310, wherein the weight compensating device 210 and the Lorentz actuators 220, 230 can continue to have one and the same point of force introduction at the mirror (or at bushings mechanically connected to the mirror).

According to FIG. 2A, the Lorentz actuator 220 is used for vertical exertion of force, and the Lorentz actuator 230 is used for horizontal exertion of force. Direct vertical or horizontal fixing of the Lorentz actuators 220, 230 to the optical element 201—in contrast to attachment according to FIG. 1 in each case at an angle to the optical element 101 or the pin 115—firstly renders the use of a corresponding bushing (“yoke”) unnecessary and in this respect also allows a comparatively stiff and close mechanical connection to the optical element 201. Furthermore, the positioning, which is independent of the position of the weight compensating device 210 or the associated actuator unit, also creates additional freedom with regard to the placement of the Lorentz actuators in accordance with the specific desire relating to possibly desired targeted excitation of certain vibration modes, which can result in even more effective prevention of undesired deformations of the optical element 210.

Furthermore, the total number of Lorentz actuators can also be greater than six, wherein one or more of these Lorentz actuators may also differ from the respective weight compensating device or the other Lorentz actuators with regard to the respective point of force introduction. Here, the disclosure can once again make use of the fact that no static forces are to be exerted on the optical element via the respective Lorentz actuators, so that the exertion of parasitic forces and moments associated with different points of force introduction in principle can be kept negligibly small.

Furthermore, the placement of the Lorentz actuators according to the disclosure can be suitably selected in such a way that—according to the concept of “overactuation” known per se—individual vibration modes are deliberately excited to a greater or lesser extent. Here, the Lorentz actuators can for example be placed in such a way that the tasks existing in the specific configuration, such as position control, feedforward control of a scanning movement of the optical element and vibration damping, can be optimally fulfilled.

FIG. 2B shows an embodiment that has been modified in comparison to FIG. 2A insofar as the Lorentz actuators (denoted 220′ and, respectively, 230′ in FIG. 2B) are also arranged within the actuator unit comprising the weight compensating device 210.

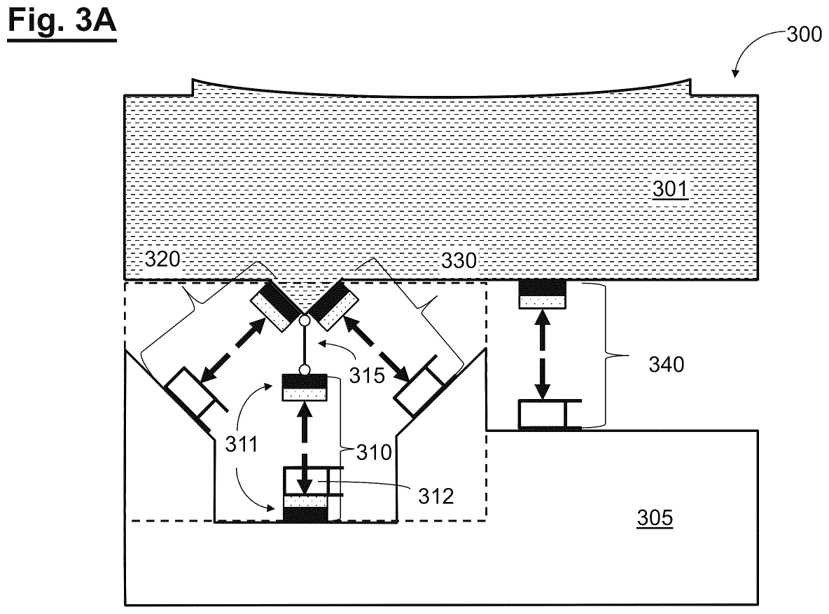

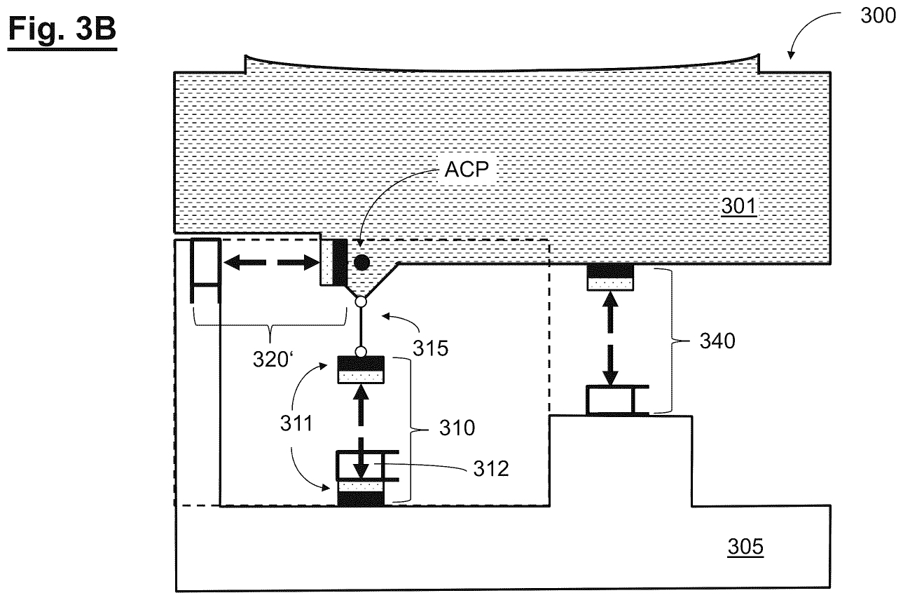

FIG. 3A shows a schematic representation of a further embodiment of an assembly 300 according to the disclosure, wherein analogous or substantially functionally identical components in comparison to FIG. 1 are denoted by reference numerals increased by “200”.

The embodiment according to FIG. 3A differs from that of FIG. 1 firstly in that the Lorentz actuators 320, 330 arranged at an angle to the optical element 301 or point of force introduction are actuated in the opposite direction, with the result that these two Lorentz actuators 320, 330 exert force horizontally on the optical element 301 overall. According to FIG. 3A, dynamic vertical exertion of force takes place via a separate Lorentz actuator 340, which is arranged outside the actuator unit comprising the weight compensating device 310 and the Lorentz actuators 320, 330.

FIG. 3B shows an embodiment that has been modified in comparison to FIG. 3A insofar as a horizontal Lorentz actuator (denoted “320” in FIG. 3B) is provided instead of the “bipod configuration” provided according to FIG. 3A. In this case, a vertical Lorentz actuator 340 and also further additional actuators can be placed outside the actuator unit, such as by dispensing with a vertical Lorentz actuator within the actuator unit comprising the weight compensating device 310—and a corresponding reduction in the installation space used within the actuator unit.

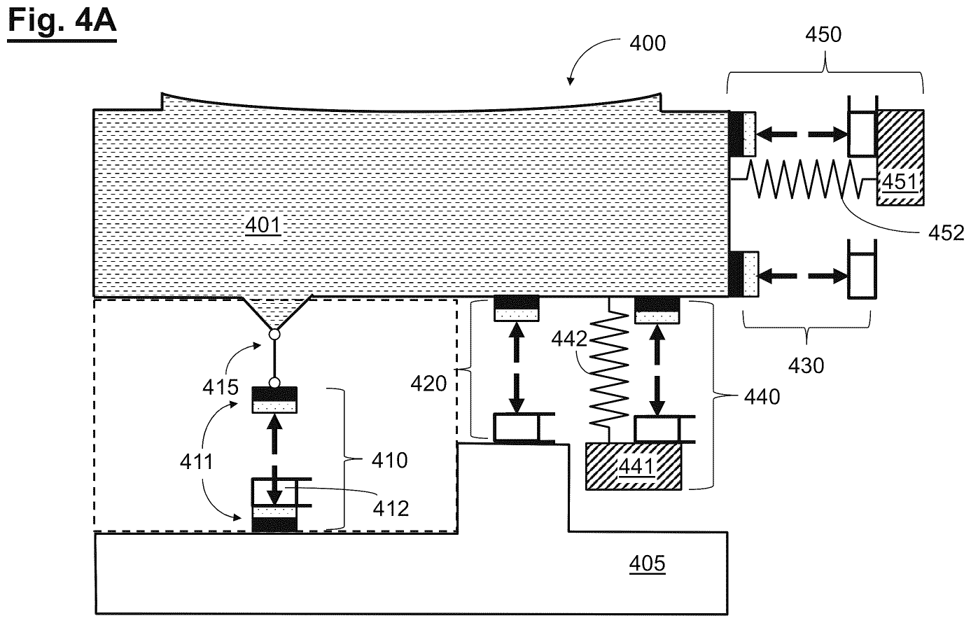

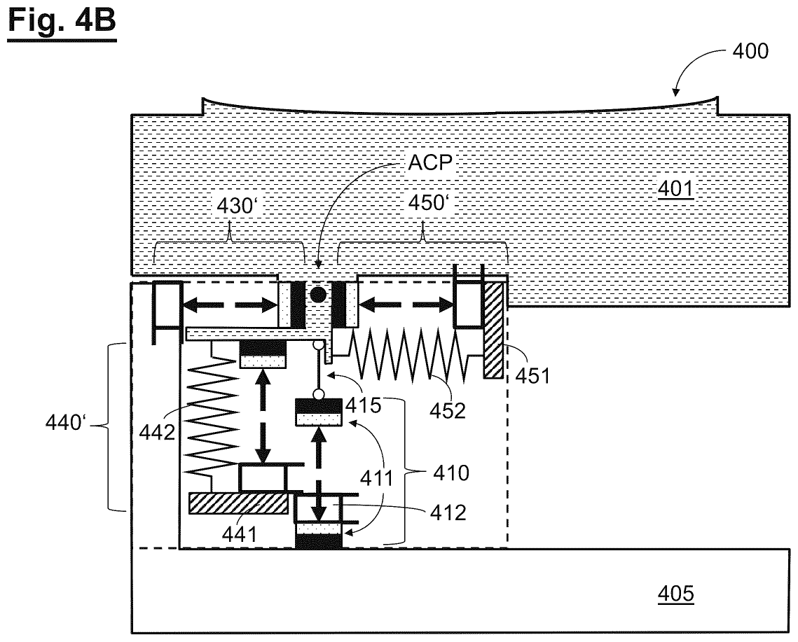

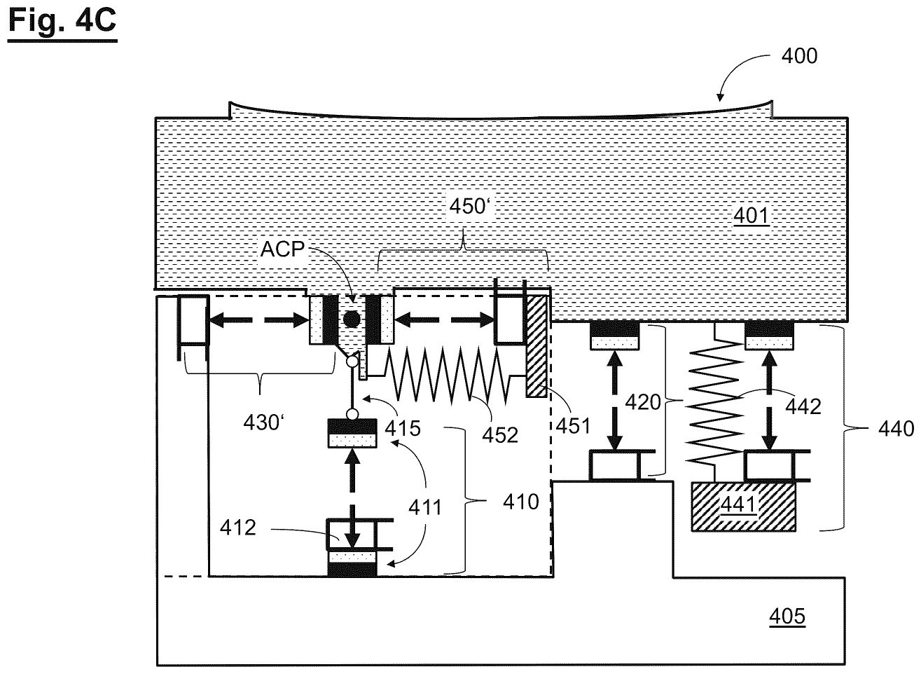

FIG. 4A shows a schematic representation of a further embodiment of an assembly 400, wherein analogous or substantially functionally identical components in comparison to FIG. 2A are denoted by reference numerals increased by “200”.

The embodiment according to FIG. 4A differs from that of FIG. 2A in that, in addition to the Lorentz actuator 420 provided for vertical exertion of force on the optical element 401 and the Lorentz actuator 430 provided for horizontal exertion of force, inertial actuators 440, 450 are provided, which each comprise an auxiliary mass 441 or 451 mechanically connected to the optical element 401 via a spring 442 or 452 in a manner known per se. The respective auxiliary mass 441 or 451 can be used to partially interrupt the reaction path associated with the exertion of force to the optical element 401, specifically above a certain limit frequency (of for example 50 Hz).

The above-described use of inertial actuators 440, 450 in an assembly in line with the concept according to the disclosure is also desirable insofar as use can be made of the fact that, as a result of “active” configuration of the weight compensating device 410, the forces below the limit frequency of the inertial actuators 440, 450 can be transmitted by the weight compensating device 410, so that—unlike otherwise usually the case with the use of inertial actuators—no additional Lorentz actuators are used for low-frequency force transmission.

The concept of overactuation already described above can also be combined in combination with the use of inertial actuators described with reference to FIG. 4A, whereby, as a result, a desirable implementation of position control, active vibration damping and scanning movement feedforward control with simultaneous decoupling of the reaction path due to inertial actuation and control can be achieved. Here, a suitable division of tasks may be that the application of feedforward control forces for a scanning movement is performed via the Lorentz actuators, the active vibration damping is implemented solely by the inertial actuators and a frequency filter is used for position control for the combined use of Lorentz actuators and inertial actuators in accordance with the inertial actuation and control concept known per se. The placement of the inertial actuators can thus be selected with regard to carrying out position control and active vibration damping in as optimum a manner as possible, whereas the Lorentz actuators can be placed independently of this with regard to optimal implementation of the scanning movement feedforward control.

FIG. 4B shows an embodiment that has been modified in comparison to FIG. 4A insofar as all of the actuators illustrated (i.e. both Lorentz actuators and inertial actuators) are arranged within the actuator unit comprising the weight compensating device 410.

FIG. 4C shows an embodiment modified with respect to FIG. 4A insofar as according to FIG. 4C (and also in FIG. 4B) both the horizontal Lorentz actuator 430′ and the horizontal inertial actuator 450′ are arranged within the actuator unit comprising the weight compensating device 410, whereas a vertical inertial actuator 440 is arranged outside the actuator unit, in contrast to FIG. 4B.

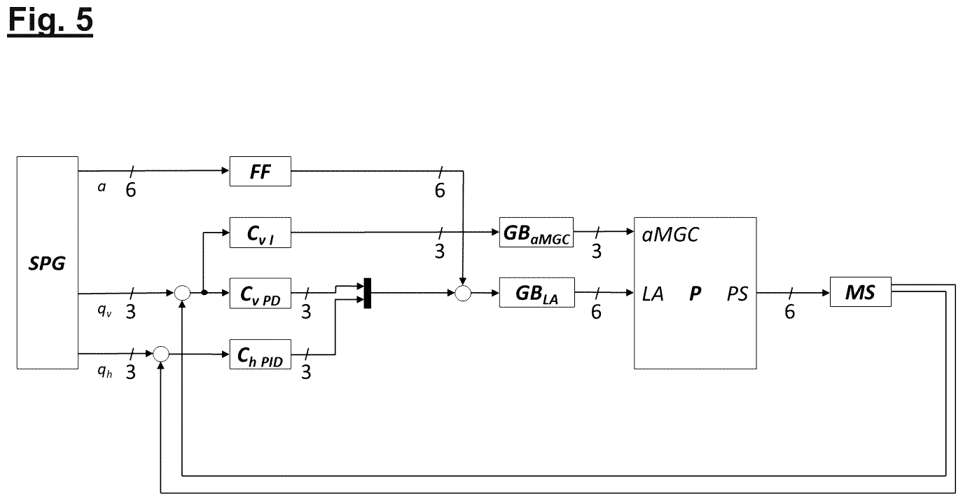

Suitable controller architectures are described below with reference to FIGS. 5-11, via which an assembly according to the disclosure can be actuated or controlled in line with the embodiments described above. A feature of the controller architecture according to the disclosure here is the separation of the (such as vertical) static forces from the (such as vertical) dynamic forces, wherein as described above the weight compensating device is actuated for exerting the static forces, whereas the Lorentz actuators are actuated for exerting the dynamic forces.

In the controller architecture of FIG. 5, actuation of a total of three weight compensating devices and a total of six Lorentz actuators is assumed, wherein six position sensors (“PS”) are also used. “SPG” denotes a target value generator in FIG. 5. “MS” denotes a coordinate transformation of the sensor signals supplied by the position sensors PS to a reference point to be controlled and a coordinate system. According to FIG. 5, a feedforward control signal is also applied via a feedforward control branch, denoted “FF”, to implement a desired movement of the optical element according to a specified trajectory via the Lorentz actuators, thereby relieving the remaining control of this scanning movement.

The abovementioned separation of static and dynamic forces is implemented in accordance with FIG. 5 in such a way that a PID controller is divided into an I component (=integrator branch) and a PD component, wherein the I component is supplied to the active weight compensating device (denoted “aMGC” in FIG. 5) via a suitable coordinate transformation and decoupling matrix GB_{aMGC}. The output of the PD component is in turn transferred to the (vertical) Lorentz actuators (denoted “LA” in FIG. 5) via a suitable coordinate transformation and decoupling matrix GB_{LA}. Since the static control error becomes zero due to the I component of the controller, the static component of the PD component also becomes zero. The deflection dependency of the force application point and the direction of force of the Lorentz actuators LA can be compensated for by deflection-dependent gain scheduling of the feedforward control matrix and the coordinate transformation and decoupling matrix.

In further embodiments, the separation according to the disclosure of the static forces from the dynamic forces can also be implemented via a frequency filter with a low-pass filter and a high-pass filter (wherein the sum of the transmission functions of low-pass and high-pass filters should be approximately one).

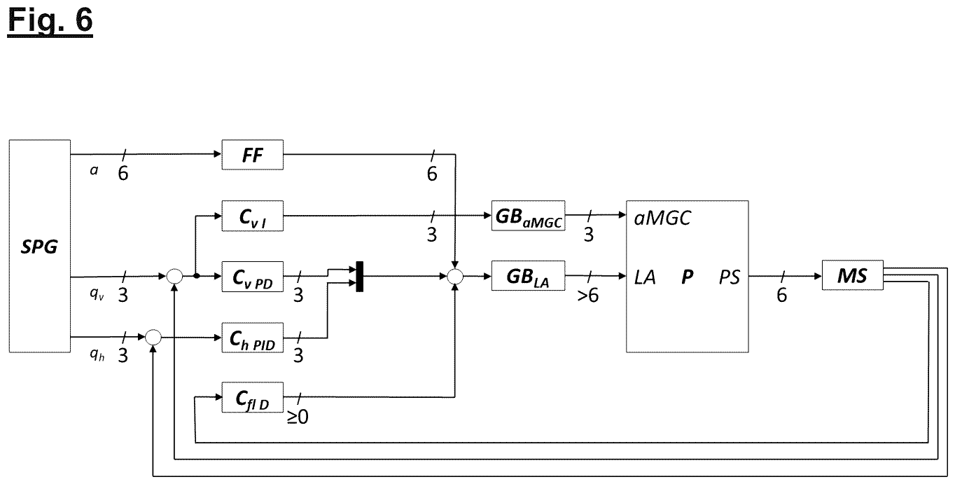

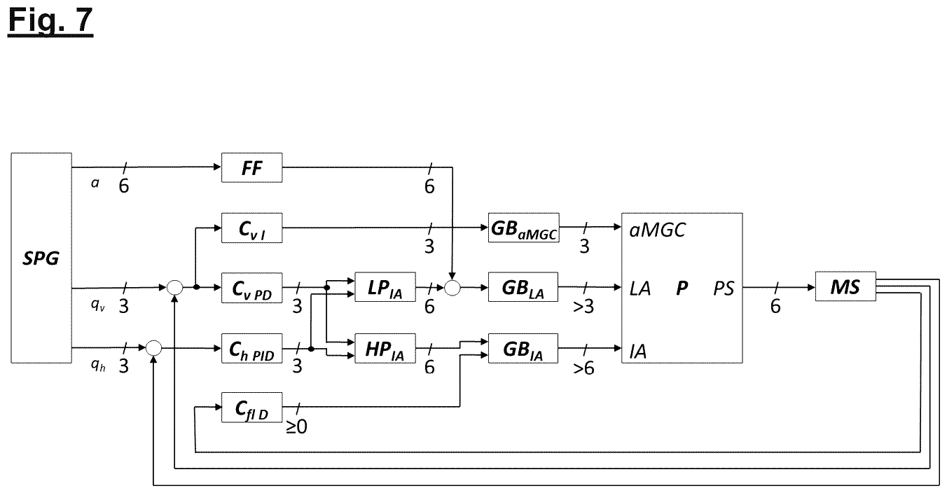

FIG. 6 shows a controller architecture analogous to FIG. 5 for the above-described concept with “overactuation”, wherein three weight compensating devices, but more than six Lorentz actuators, are furthermore used. FIG. 7 shows a controller architecture with additional consideration of the use (for example in accordance with the embodiment of FIG. 4A) of inertial actuators. In this case, according to FIG. 7, the feedforward control signal is applied analogously to FIG. 5 and FIG. 6 via the feedforward branch FF and via the Lorentz actuators LA. In alternative embodiments, the feedforward control signal can also be distributed to Lorentz actuators and inertial actuators via another frequency filter, wherein in this case larger forces and deflections of the inertial actuators may have to be accepted. In the event of an overactuation being implemented, the active vibration damping can be performed solely via the inertial actuators. The position control can distribute the forces to Lorentz actuators and inertial actuators in accordance with the inertial actuation and control concept known per se via a further frequency filter.

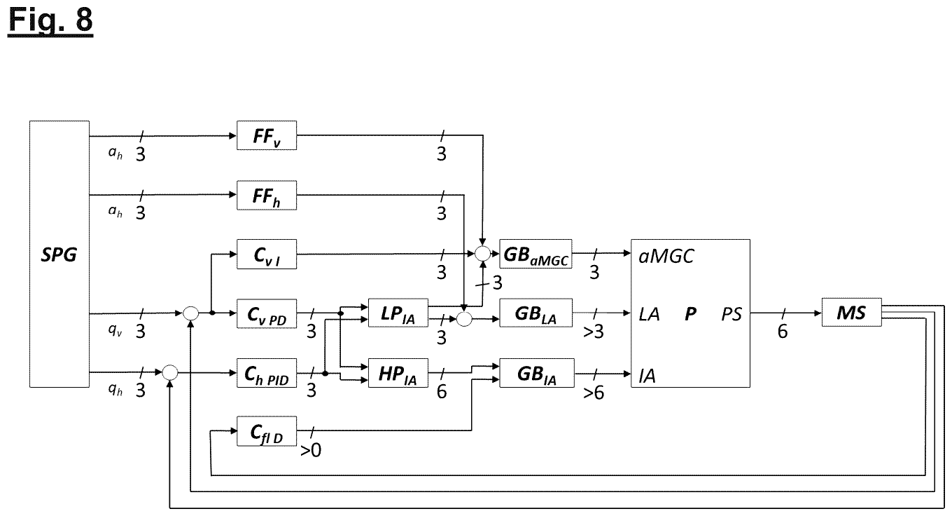

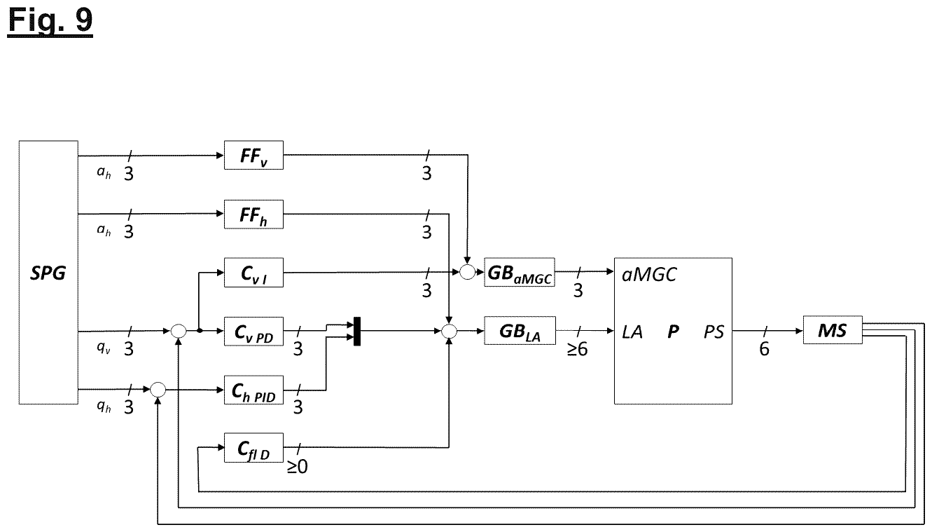

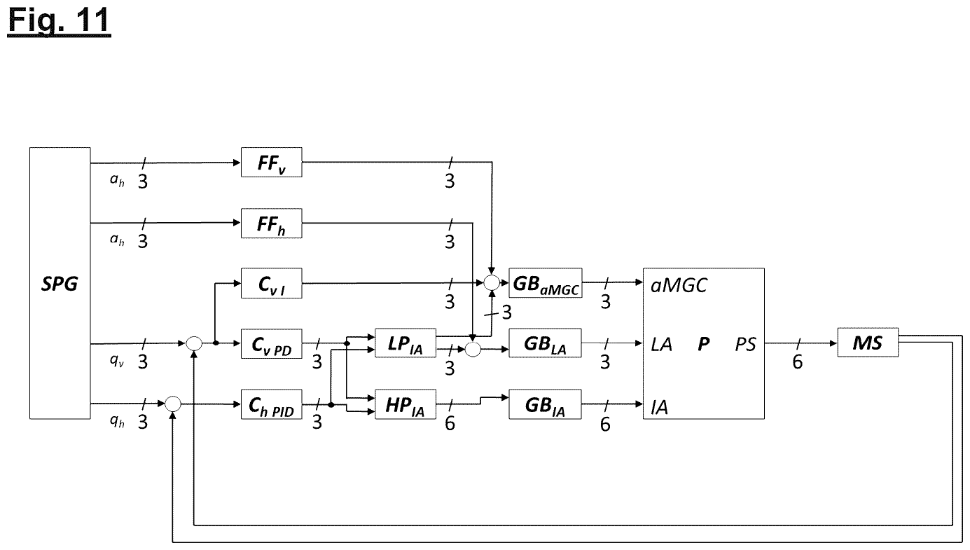

FIG. 8, FIG. 9 and FIG. 11 show controller architectures in which, in contrast to the embodiments described above, the feedforward control branch FF is divided into a “vertical” feedforward control branch FF_{V} and a “horizontal” feedforward control branch FF_{H} for implementing a desired movement of the optical element, wherein the signal of the “vertical” feedforward branch FF_{V} is conducted via the active weight compensating device, as a result of which parasitic forces and moments can be reduced during the scanning process. In this case, the controller architectures according to FIG. 8 and FIG. 11—in this respect analogously to FIG. 7—are configured with additional consideration of the use (for example according to the embodiments of FIGS. 4A-4C) of inertial actuators.

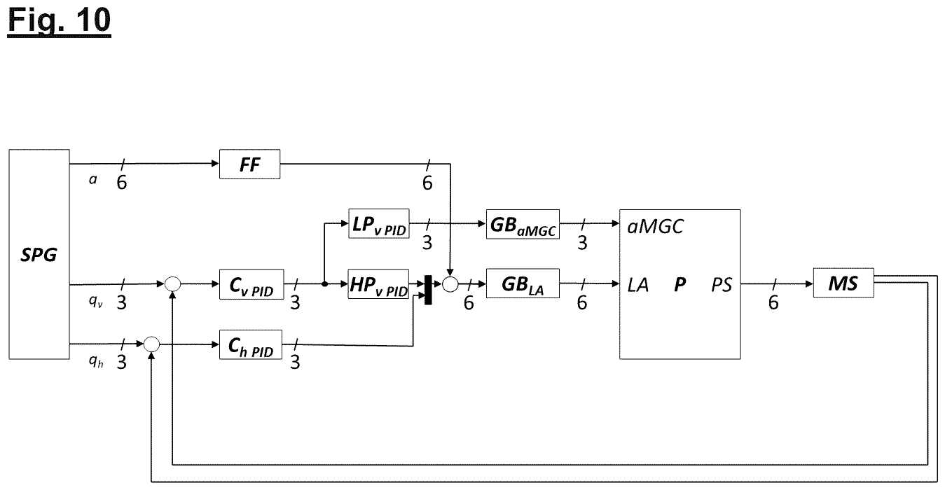

FIG. 10 shows a controller architecture in which, analogously to FIG. 7, a frequency filter with a low-pass filter and a high-pass filter is used, wherein no inertial actuators are present here, in contrast to FIG. 7.

In order to simplify the wiring, the actuators can be actuated via local amplifiers, which are actuated via a field bus. In this case, only one field bus cable and one power supply cable are used.

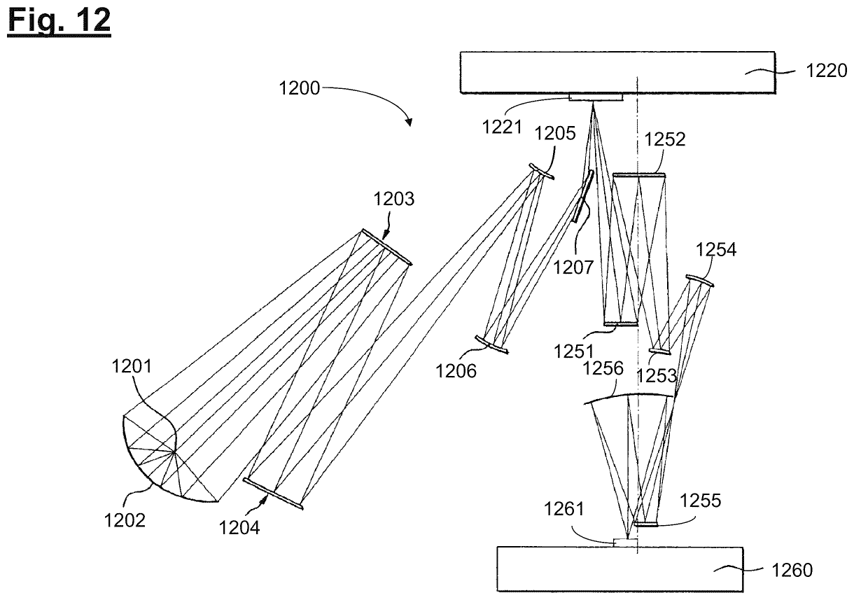

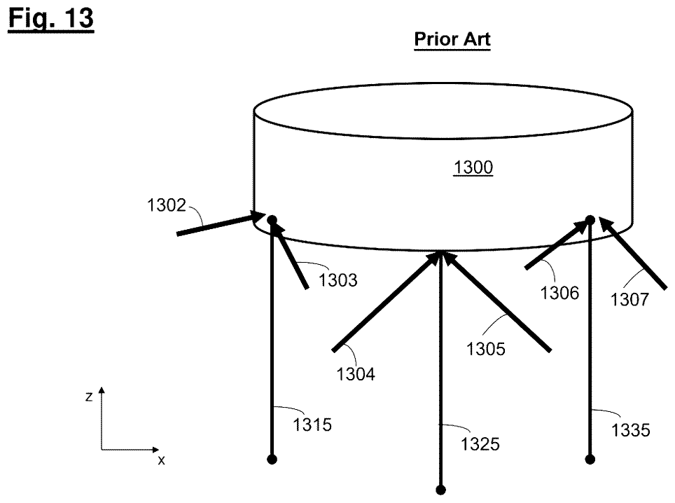

FIG. 12 shows a merely schematic representation of a projection exposure apparatus 1200 which is designed for operation in the EUV range and in which the present disclosure can be implemented by way of example.

According to FIG. 12, an illumination device of the projection exposure apparatus 1200 has a field facet mirror 1203 and a pupil facet mirror 1204. The light from a light source unit comprising a plasma light source 1201 and a collector mirror 1202 is directed to the field facet mirror 1203. A first telescope mirror 1205 and a second telescope mirror 1206 are arranged downstream of the pupil facet mirror 1204 in the light path. A deflection mirror 1207 operated with grazing incidence is arranged downstream in the light path and directs the radiation impinging on it onto an object field in the object plane of a projection lens with mirrors 1251-1256, which is merely indicated in FIG. 12. At the location of the object field, a reflective structure-bearing mask 1221 is arranged on a mask stage 1220, the mask being imaged with the aid of a projection lens into an image plane in which a substrate 1261 coated with a light-sensitive layer (photoresist) is situated on a wafer stage 1260.

Even though the disclosure has been described on the basis of specific embodiments, numerous variations and alternative embodiments will be apparent to a person skilled in the art, for example by combining and/or exchanging features of individual embodiments. Accordingly, it goes without saying for a person skilled in the art that such variations and alternative embodiments are also included by the present disclosure, and the scope of the disclosure is restricted only within the meaning of the accompanying claims and the equivalents thereof.

What is claimed is:

1. An assembly, comprising:
an optical element;
a weight compensating device, comprising:
a passive magnetic circuit configured to generate a magnetic field to cause a force to at least partially compensate a weight acting on the optical element; and
an active component configured to generate an actively controllable force transmitted to the optical element;
a pin mounted in an articulated manner and coupling the weight compensating device to the optical element; and
first, second and third Lorentz actuators,
wherein each of the first, second and third Lorentz actuators is configured to exert a controllable force on the optical element, and the first Lorentz actuator is fixed directly to the optical element.

2. The assembly of claim 1, wherein the active component comprises a coil configured to have electric current applied thereto.

3. The assembly of claim 1, wherein each of the second and third Lorentz actuators is fixed directly to the optical element.

4. The assembly of claim 1, further comprising fourth, fifth and six Lorentz actuators, wherein each of the fourth, fifth and sixth Lorentz actuators is configured to exert a controllable force on the optical element, and each of the second, third, fourth, fifth and sixth Lorentz actuators is fixed directly to the optical element.

5. The assembly of claim 1, wherein the coupling has a natural frequency that is less than three times a control bandwidth.

6. The assembly of claim 1, further comprising a further weight compensating device, wherein the further weight compensating device comprises:
a passive magnetic circuit configured to generate a magnetic field to cause a force to at least partially compensate a weight acting on the optical element; and
an active component configured to generate an actively controllable force transmitted to the optical element.

7. The assembly of claim 1, comprising three actuator units, wherein for each of the three actuator units:
the actuator unit comprises a weight compensating device and two Lorentz actuators; and
the two Lorentz actuators and the weight compensating device run to a common point of force introduction.

8. The assembly of claim 1, comprising three actuator units, wherein for each of the three actuator units:
the actuator unit comprises a weight compensating device, a Lorentz actuator and an inertial actuator; and
the Lorentz actuator, the inertial actuator and the weight compensating device run to a common point of force introduction.

9. The assembly of claim 1, comprising more than three Lorentz actuators, wherein each of the more than three Lorentz actuators is configured to exert a controllable force on the optical element in a vertical direction.

10. The assembly of claim 1, comprising six Lorentz actuators, wherein each of the six Lorentz actuators is configured to exert a controllable force on the optical element in a vertical direction.

11. The assembly of claim 1, further comprising at least three inertial actuators configured to exert a controllable force on the optical element to partially decouple a reaction path accompanying the exertion of the controllable force on the optical element.

12. The assembly of claim 1, further comprising six inertial actuators configured to exert a controllable force on the optical element to partially decouple a reaction path accompanying the exertion of the controllable force on the optical element.

13. The assembly of claim 1, further comprising a controller configured to separately actuate: i) the weight compensating device to exert static forces; and ii) the first, second and third Lorentz actuators to exert dynamic forces.

14. The assembly of claim 13, wherein the controller comprises a PID controller comprising an integrator (I) branch and a separate PD branch, and the PID controller is configured to actuate: a) the weight compensating device via the integrator branch; and b) the first, second and third Lorentz actuators via the PD branch.

15. The assembly of claim 1, wherein the optical element comprises a mirror.

16. The assembly of claim 15, wherein the active component comprises a coil configured to have electric current applied thereto.

17. A system, comprising:
an assembly according to claim 1,
wherein the system comprises an optical system.

18. The system of claim 17, wherein the optical system comprises a microlithographic illumination device.

19. The system of claim 17, wherein the optical system comprises a microlithographic projection lens.

20. An apparatus, comprising:
an assembly according to claim 1,
wherein the apparatus comprises a microlithographic projection exposure apparatus.
